(19) United States
(12) Patent Application Publication
(10) Pub. No.: US 2007/0272928 A1
(43) Pub. Date: Nov. 29, 2007

(54) THIN FILM TRANSISTOR, ARRAY SUBSTRATE HAVING THE THIN FILM TRANSISTOR AND METHOD OF MANUFACTURING THE ARRAY SUBSTRATE

(76) Inventors: Ji-Yong Park, Suwon-si (KR); Dong-Byum Kim, Seoul (KR); Jung-Hyun Kim, Seoul (KR); Chung Yi, Yongin-si (KR)

Correspondence Address: F. CHAU & ASSOCIATES, LLC, 130 WOODBURY ROAD, WOODBURY, NY, 11797, US

(21) Appl. No.: 11/751,743

(22) Filed: May 22, 2007

(30) Foreign Application Priority Data
May 26, 2006 (KR) 2006-47405

(51) Int. Cl. H01L 29/04; H01L 21/84

(52) U.S. Cl. 257/72; 438/151; 257/E27.132

(57) ABSTRACT

A thin film transistor includes a semiconductor layer a source electrodes a drain electrode and a gate electrode. The semiconductor layer includes a plurality of grain boundaries disposed along a first direction. An acute angle between a gate electrode and a grain boundary prevents grain to boundaries from being formed at the boundary between a channel part and an ion doped part.

### CROSS-REFERENCE TO RELATED APPLICATION

This application claims priority to Korean Patent Application No. 2006-47405 filed on May 26, 2006, the disclosure of which is incorporated by reference in its entirety.

### BACKGROUND OF THE INVENTION

1. Technical Field

The present invention relates to a thin film transistor, an array substrate having the thin film transistor and a method of manufacturing the array substrate, and more particularly, to a thin film transistor having enhanced electrical properties.

2. Discussion of the Related Art

An amorphous silicon (a-Si) thin film transistor may be used as a switching device of a liquid crystal display (LCD). A polysilicon (poly-Si) thin film transistor having a relatively faster operating speed may be more likely used in a liquid crystal display (LCD) of mobile devices to reduce the manufacturing cost and to obtain a highly fine structure by directly integrating circuits on a substrate. For example, in an organic light emitting display having an organic light emitting diode (OLED) which is driven by electric current, the polysilicon (poly-Si) thin film transistor may be mainly used.

A polysilicon (poly-Si) thin film used for the polysilicon (poly-Si) thin film transistor may be formed by scanning laser beam to crystallize an amorphous silicon thin film. The laser beam is irradiated onto a region of the amorphous silicon thin film through a mask having a plurality of slits.

Sequential lateral solidification (SLS) crystallizing method may be used for forming the polysilicon (poly-Si) thin film. The SLS crystallizing method is to crystallize the whole region of the amorphous silicon thin film by moving the mask in a direction and simultaneously scanning the laser beam. When the polysilicon (poly-Si) thin film is formed by the SLS crystallizing method, grain boundaries are formed along the predetermined direction on the polysilicon (poly-Si) thin film.

A semi-conductor layer is formed by patterning a region of the polysilicon (poly-Si) thin film. A source electrode and a drain electrode are formed on the semiconductor layer. Then, the polysilicon (poly-Si) thin film transistor is formed.

However, the grain boundaries may exist in the semiconductor layer. Thus, the grain boundaries can deteriorate electrical properties, for example, such as electrical mobility. When patterning position is changed according to a manufacturing process, positions or figures of grain boundaries in a channel of the semiconductor layer may be changed. As a result, electrical properties can be changed.

### SUMMARY OF THE INVENTION

Embodiments of the present invention provide a thin film transistor capable of enhancing electric properties by preventing patterning errors, an array substrate having the above thin film transistor, and a method of manufacturing the above array substrate.

The thin film transistor according to an exemplary embodiment of the present invention includes a semiconductor layer, a source electrode, a drain electrode and a gate electrode. The semiconductor layer includes a plurality of grain boundaries disposed along a first direction. The source and drain to electrodes are adjacent to each other. The gate electrode faces the source and drain electrode with the semiconductor layer interposed between the gate electrode and the source and drain electrodes. The gate electrode includes a side surface forming an acute angle θ with respect to the second direction substantially perpendicular to the first direction the acute angle θ being represented by the following equation:

tan(θ)=W/G,

wherein G is a distance between the grain boundaries, and W is a width of the semiconductor layer toward the first direction.

For example, a width L of the gate electrode in the second direction satisfies the following equation:

L=n×G,

wherein n is a natural number.

The array substrate includes pixel electrodes disposed in a matrix and a plurality of thin film transistors driving the pixel electrodes. Each of the thin film transistors includes a semiconductor layer having a plurality of grain boundaries disposed along a first direction, a source electrode, a drain electrode and a gate electrode. The source and drain electrodes are adjacent to each other. The gate electrode faces the source and drain electrode with the semiconductor layer interposed between the gate electrode and the source and drain electrodes. The gate electrode includes a side surface forming an acute angle θ with respect to a second direction substantially to perpendicular to the first direction, the acute angle θ being represented by the following equation:

tan(θ)=W/G,

wherein G is a distance between the grain boundaries, and W is a width of the semiconductor layer toward the first direction.

The method of manufacturing an array substrate includes forming a semiconductor layer having a plurality of grain boundaries along a first direction on a transparent substrate, forming a gate electrode along a third direction making an acute angle with a second direction substantially perpendicular to the first direction, the gate electrode partially overlapping the semiconductor layer and forming a source electrode electrically connected to a first portion of the semiconductor layer and a drain electrode electrically connected to a second portion of the semiconductor layer.

According to exemplary embodiments of the present invention, an acute angle between a gate electrode and a grain boundary prevents grain boundaries from being formed at a boundary between a channel part and an ion doped part. As a result, electrical mobility of a semiconductor layer is enhanced.

### BRIEF DESCRIPTION OF THE DRAWINGS

Exemplary embodiments of the present invention can be understood in more detail from the following descriptions taken in conjunction with the accompanying drawings, in which:

FIG. 1 is a plan view illustrating a region of an array substrate in accordance with an embodiment of the present invention;

FIG. 2 is an enlarged plan view showing a part A in FIG. 1;

FIG. 3 is a cross-sectional view taken along a line I-I′ in FIG. 2;

FIG. 4 is another plan view showing a part A in FIG. 1;

FIG. 5 is a plan view showing a semiconductor layer and a gate electrode in FIG. 2;

FIG. 6 is a cross-sectional view taken along a line II-II′ in FIG. 5;

FIG. 7 is a plan view showing a semiconductor layer and a gate electrode in FIG. 5 having different positions of grain boundaries;

FIG. 8 is a plan view showing a gate electrode and grain boundaries having positions changed to overlap each other in FIG. 7;

FIG. 9 is a plan view showing the relation between a gate electrode and grain boundaries, when width of the gate electrode is n-times of a distance between the grain boundaries;

FIG. 10 is a plan view showing the relation between a gate electrode and grain boundaries, when width of the gate electrode is not n-times of distance between the grain boundaries; and

FIGS. 11 to 14 are plan views showing a method of manufacturing an array substrate in accordance with an embodiment of the present invention.

### DESCRIPTION OF THE EXEMPLARY EMBODIMENTS

Exemplary embodiments of the invention are described more fully hereinafter with reference to the accompanying drawings. This invention may, however, be embodied in many different forms and should not be construed as limited to the embodiments set forth herein.

In an embodiment, a display panel includes an array substrate, an opposite substrate and a liquid crystal layer.

The array substrate includes a plurality of pixel electrodes, thin film transistors and signal lines. The pixel electrodes are disposed in a matrix. The thin film transistors apply driving voltages to the pixel electrodes, respectively. The signal lines provide signal voltages to the thin film transistors, respectively.

The opposite substrate faces the array substrate. The opposite substrate may include a transparent and conductive common electrode and color filters. The color filters are disposed at a position corresponding to the pixel electrodes, respectively. For example, the color filters may include, for example, a red color filter, a green color filter and a blue color filter.

The liquid crystal layer is disposed between the array substrate and the opposite substrate. Liquid crystal molecules of the liquid crystal layer vary their arrangement in response to an electric field generated between the pixel electrodes and the common electrode. The liquid crystal layer controls light transmissivity of an externally provided light. The controlled light passes through the color filters, thereby displaying images.

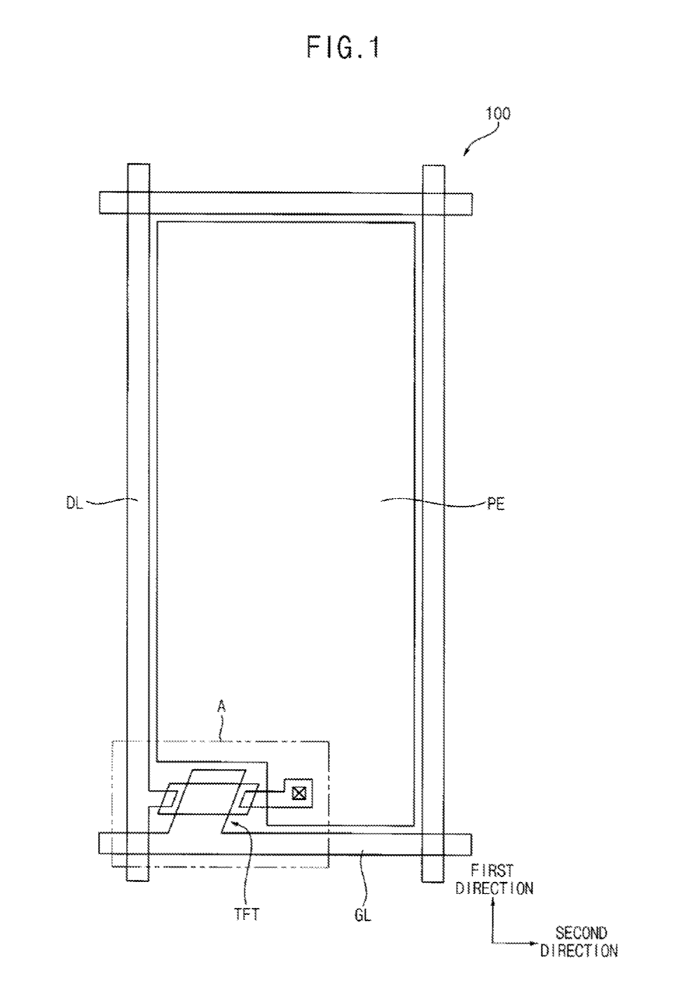

FIG. 1 is a plan view illustrating a region of an array substrate in accordance with an embodiment of the present invention.

Referring to FIG. 1, an array substrate 100 includes data lines DL, gate lines GL, thin film transistors TFTs and pixel electrodes PEs.

The data lines DL are formed toward a first direction. The data lines DL are disposed along a second direction substantially perpendicular to the first direction. The data lines DL are substantially parallel with each other. Distance between the data lines DL is substantially constant. The gate lines GL cross the data lines DL toward the second direction. The gate lines GL are substantially parallel with each other. Distance between the gate lines GL is substantially constant.

The data lines DL and gate lines GL crossing each other define a plurality of unit regions. For example, each of the unit regions includes a thin film transistor TFT and a pixel electrode PE. The thin film transistor TFT is disposed at a portion of the unit region, and the pixel electrode PE is disposed at substantially the entire unit region.

The thin film transistor TFT is electrically connected to the data lines DL and the gate lines GL. The thin film transistor TFT is electrically connected to a pixel electrode PE, and applies drive voltage to the pixel electrode PE. The pixel electrode PE is charged from the drive voltage, and generates an electric field between the pixel electrode PE and a common electrode of the opposite substrate.

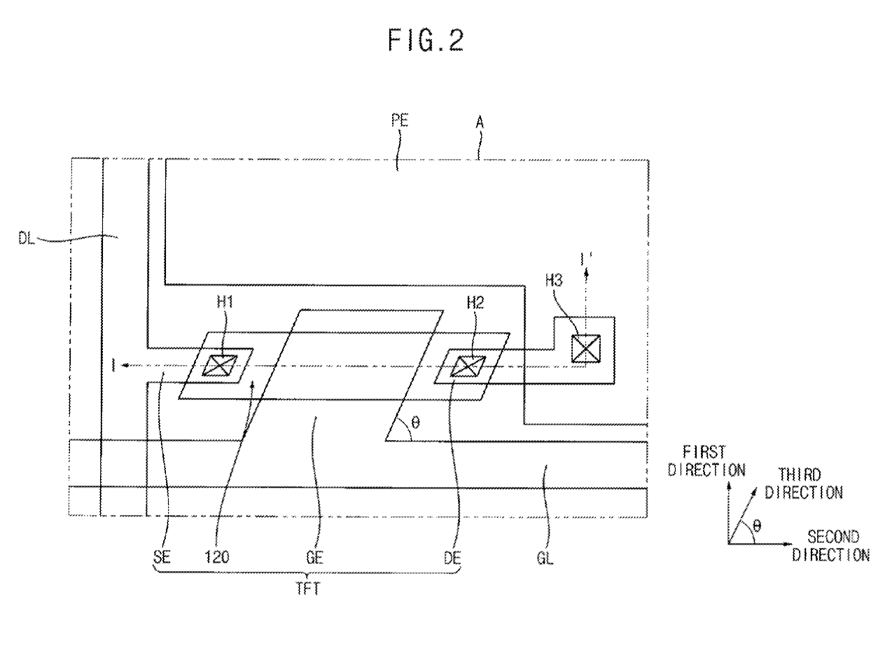

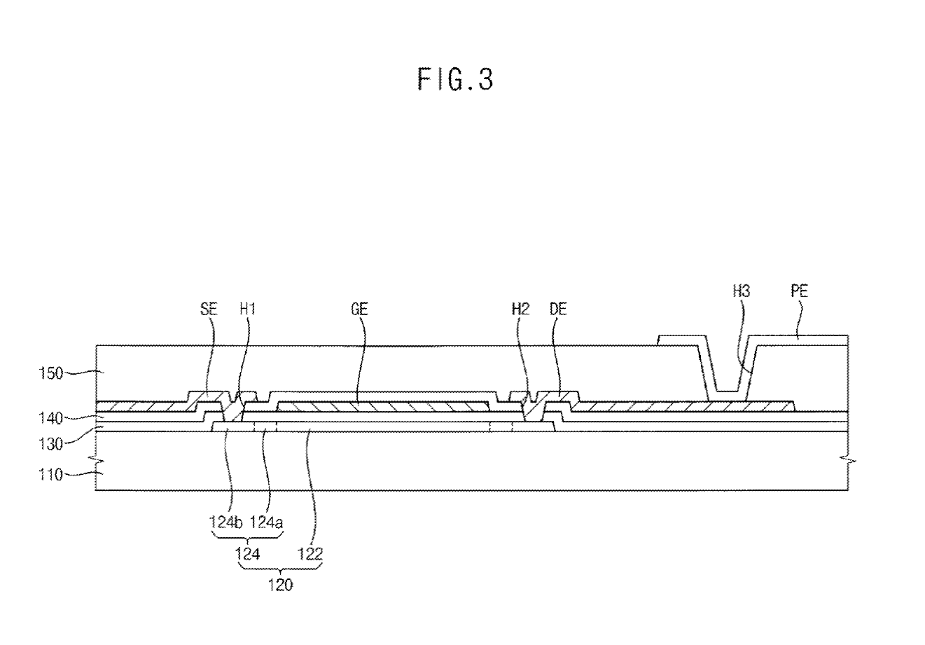

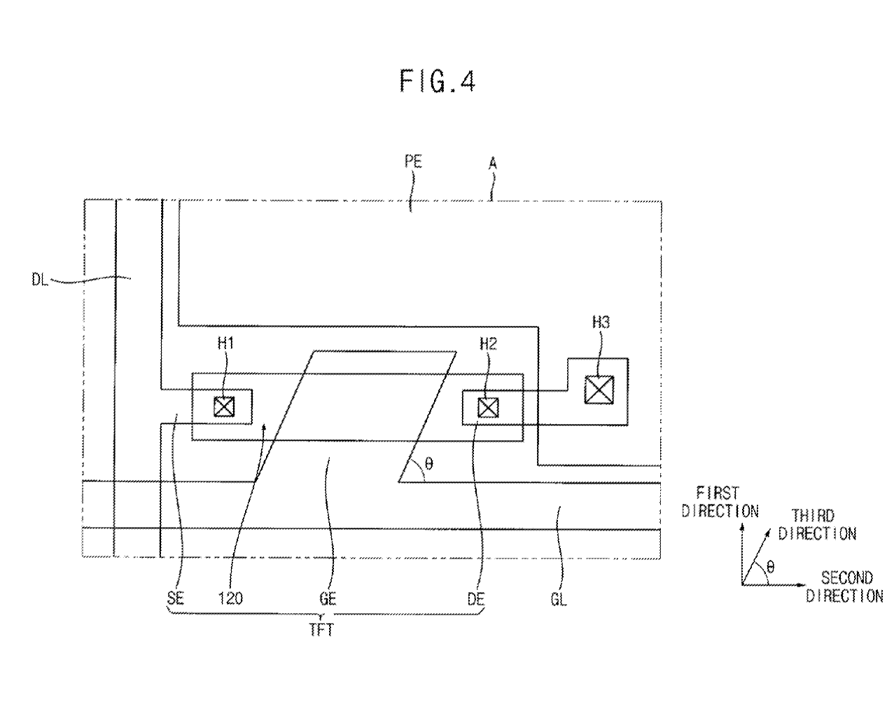

FIG. 2 is an enlarged plan view showing a part A in FIG. 1. FIG. 3 is a cross-sectional view taken along a line I-I′ in FIG. 2. FIG. 4 is another plan view showing a part A of FIG. 1.

Referring to FIG. 2 and FIG. 3, an array substrate 100 includes a transparent substrate 110, semiconductor layers 120, a first insulating layer 130, gate lines GL, gate electrodes GE, a second insulating layer, data lines DL, source electrodes SE, drain electrodes DE, a protecting layer 150 and pixel electrodes PE. The thin film transistor TFT includes a semiconductor layer 120, a gate electrode GE, a source electrode SE and a drain electrode DE.

The transparent substrate 110 has a shape of a plate, and may include, for example, transparent material, such as, glass, quartz and/or transparent synthetic resins.

The semiconductor layer 120 is disposed on the transparent substrate 110. The semiconductor layer 120 is disposed along the second direction. The semiconductor 120 includes poly silicon. The poly silicon may be formed by crystallizing amorphous silicon.

The semiconductor 120 includes a channel part 122 and an ion doped part 124 disposed at both sides of the channel part 122. Ions are doped in the ion doped part 124. As a result, the ion doped part 124 has higher electrical mobility than the channel part 122.

The ion doped part 124 includes a low density doped part 124a and a high density doped part 124b. The low density doped part 124a is disposed at both sides of the channel part 122. The ions are doped in the low density to doped part 124a at a relatively low density.

Meanwhile, the high density doped part 124b is disposed at both edges of the low density doped part 124a. The ions are doped in the high density doped part 124b at a relatively high density.

The first insulating layer 130 covers the semiconductor layer 120, and is disposed on the transparent substrate 110. For example, the first insulating layer 130 may include silicon oxide (SiOx) and/or silicon nitride (SiNx).

The gate line GL and gate electrode GE is disposed on the first insulating layer 130. The gate line GL is disposed along the second direction. The gate electrode GE is branched from the gate line GL and disposed along a third direction. The third direction and the second direction make an acute angle θ. The channel part 122 of the semiconductor layer 120 is disposed at a position where the gate electrode GE and the semiconductor layer 120 overlap each other.

The second insulating layer 140 covers gate lines GL and gate electrodes, and is disposed on the first insulating layer 120. For example, the second insulating layer 140 may include silicon oxide (SiOx) and/or silicon nitride (SiNx).

The data line DL, the source electrode SE and the drain electrode DE are disposed on the second insulating layer 140. The data line DL is disposed along the first direction. The source electrode SE is branched from the data line GL and disposed along a second direction. The source electrode SE is overlapped with a portion of the semiconductor layer 120. The drain electrode DE is disposed along the second direction from the source electrode SE. The drain electrode DE is spaced apart from the source electrode SE, and is overlapped with a portion of the semiconductor layer 120. For example, the gate electrode GE may be in the middle of the source electrode SE and the drain electrode DE.

First and second contact holes H1 and H2 are disposed at both sides of the gate electrode GE in the first and second insulating layers 130 and 140, respectively. Thus, both the source electrode SE and the drain electrode DE are electrically connected to the semiconductor layer 120. For example, the source electrode SE may be electrically connected to the semiconductor layer 120 through the first contact hole H1. The drain electrode DE is electrically connected to the semiconductor layer 120 through the second contact hole H2 For example, both the source electrode SE and the drain electrode DE electrically may be connected to the high density doped part 124b of the semiconductor layer 120.

The protecting layer 150 covers the data line DL, the source electrode SE and the drain electrode DE, and is disposed on the second insulation layer 140. For example, the protecting layer 150 may be, for example, an organic insulating layer.

The pixel electrode PE is disposed on the protecting layer 150. The pixel electrode PE is electrically connected to the drain electrode DE through a third contact hole H3. The third contact hole H3 is disposed at the protecting layer 150.

Referring again to FIG. 2, when the gate electrode GE is viewed on a plane, the gate electrode GE is a shape of a parallelogram. When a semiconductor layer 120 is viewed on a plane, the semiconductor layer 120 is a shape of a parallelogram. For example, an angle of inclination of both the gate electrode GE and the semiconductor layer 120 may be substantially the same with each other. In the other hands, referring to FIG. 4 the semiconductor layer 120 may have a shape of a rectangular.

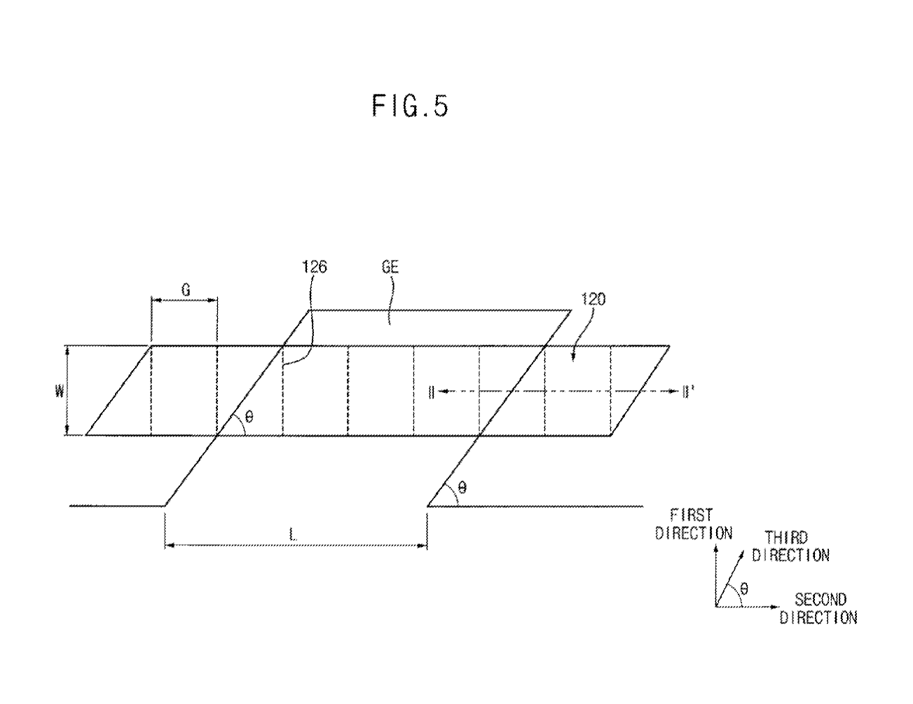

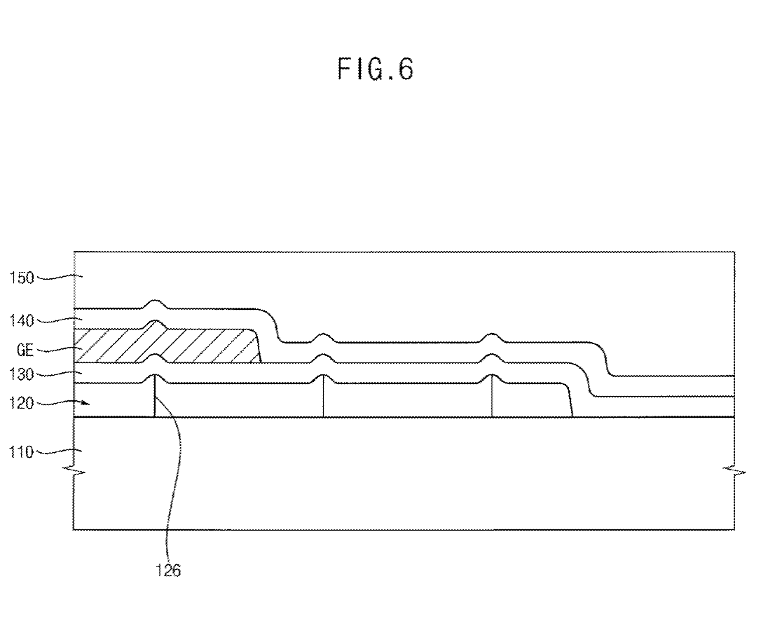

FIG. 5 is a plan view showing a semiconductor layer and a gate electrode in FIG. 2. FIG. 6 is a cross-sectional view taken along a line II-II′ in FIG. 5.

Referring to FIG. 5 and FIG. 6, a semiconductor layer 120 is disposed along a second direction. The semiconductor layer 120 includes poly silicon. The semiconductor layer 120 includes a plurality of grain boundaries 126 disposed along a first direction. For example, the grain boundaries 126 may be formed by a sequential lateral solidification (SLS) crystallization method. The sequential lateral solidification (SLS) crystallization method is performed using a laser. Thus, the grain boundaries protrude from a surface of the semiconductor layer 120 by lateral growth of a plurality of grains.

For example, a distance G between the grain boundaries 126 may have a range from about 1.5 μm to about 10 μm. For examples the distance G between the grain boundaries 126 may be a range from about 3 μm to about 3.5 μm. For example, a width W toward the first direction of the semiconductor layer 120 may have a range from about 1.5 μm to about 100 μm. In an embodiment, a width W toward the first direction of the semiconductor layer 120 may have a range from about 4 μm to about 20 μm. For example, a width L of the gate electrode GE toward the second direction may be in a range from about 1.5 μm to about 100 μm. The width L of the gate electrode GE toward the second direction may also be in a range from about 1.5 μm to about 20 μm.

For example, an acute angle θ between the second direction and the third direction, or an angle between the gate electrode GE and the second direction may be represented by the following equation 1.

tan θ=W/G [Equation 1]

In Equation 1, a width L toward the second direction of the gate electrode GE may be represented by the following equation 2.

L=n×G (n is a natural number) [Equation 2]

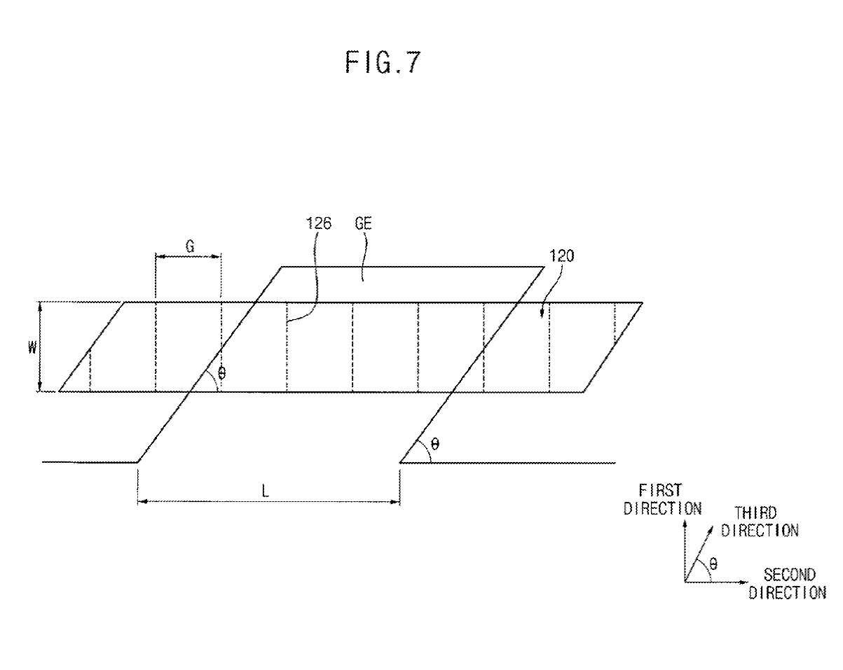

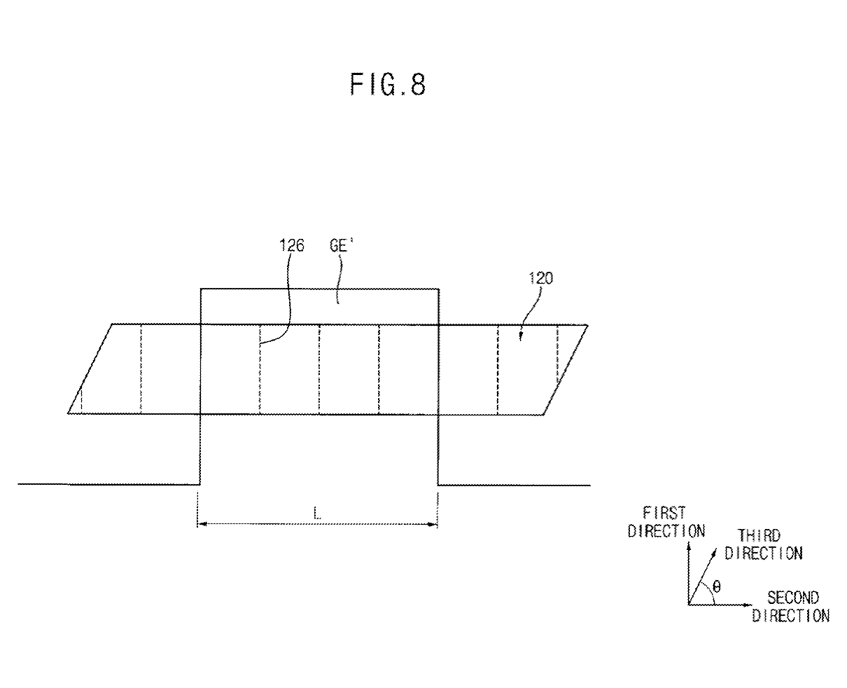

FIG. 7 is a plan view showing a semiconductor layer and a gate electrode in FIG. 5 having different positions of grain boundaries. FIG. 8 is a plan view showing a gate electrode and grain boundaries having positions changed to overlap each other in FIG. 7.

Referring to FIG. 7, the gate electrode GE makes a slope substantially parallel with a longitudinal direction of the grain boundaries 126 in the semiconductor layer 120. For example, an angle θ between the gate electrode GE and a second direction substantially perpendicular to the first to direction may be an acute angle. For example, grain boundaries 126 in FIG. 7 may be shifted in the second direction from the grain boundaries 126 in FIG. 5. When a semiconductor layer is formed by a patterning process, a fine error of patterning may occur. Thus, positions of grain boundaries 126 in FIG. 5 and FIG. 7 may be different from each other.

Referring to FIG. 8 and FIG. 3, a gate electrode GE is substantially parallel with a longitudinal direction of grain boundaries 126 in a semiconductor layer 120. A gate electrode GE having a substantially rectangular shape is shown in FIG. 8.

For example, when a side of the gate electrode GE is coincided with a direction of grain boundaries 126, both edges toward the second direction of the gate electrode GE may be coincided with the grain boundaries 126 as shown in FIG. 8.

When both edges of the gate electrode GE and the grain boundaries are coincided with each other a channel part 122 may be disposed at a region where the gate electrode GE and the semiconductor layer 120 are overlapped. Thus, an ion doped part 124 may be disposed at both sides of the channel part 122. Both sides of the channel part 122 are aligned in the second direction. A grain boundary may be disposed on a boundary of the channel part 122 and the ion doped part 124.

When a grain boundary 126 is disposed on a boundary between the channel part 122 and the ion doped part 124, electric resistance at the boundary between the channel part 122 and the ion doped part 124 may be increased in comparison with when a grain boundary 126 is not disposed on the boundary between the channel part 122 and the ion doped part 124.

Referring again to FIG. 7 and FIG. 3, since a side of the gate electrode GE is inclined with respect to an extended direction of grain boundaries 126, the grain boundaries 126 are not disposed at a boundary region between a channel part 122 and an ion doped part 124. Thus, high electric resistance at a boundary between a channel part 122 and an ion doped part 124 remains constant.

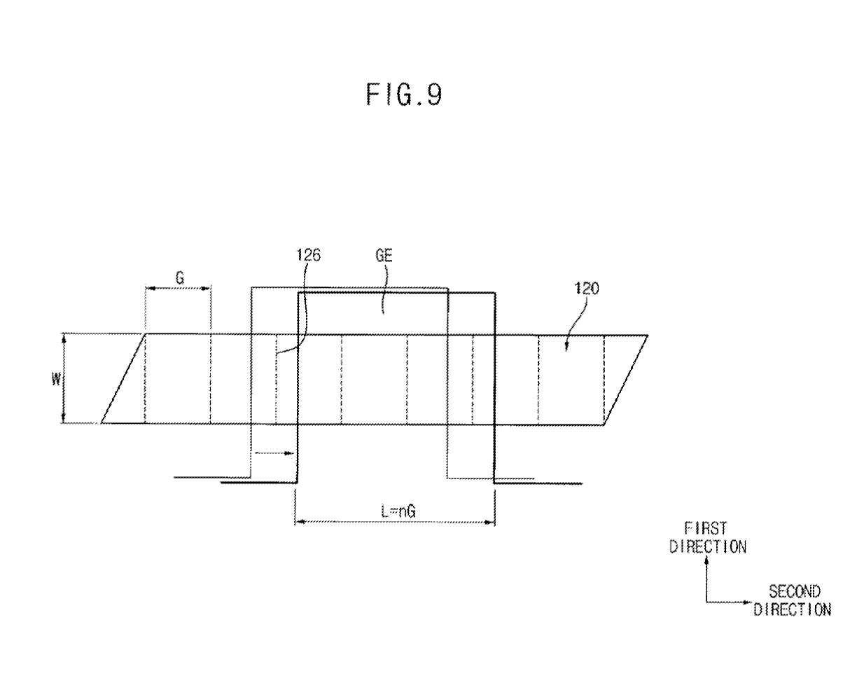

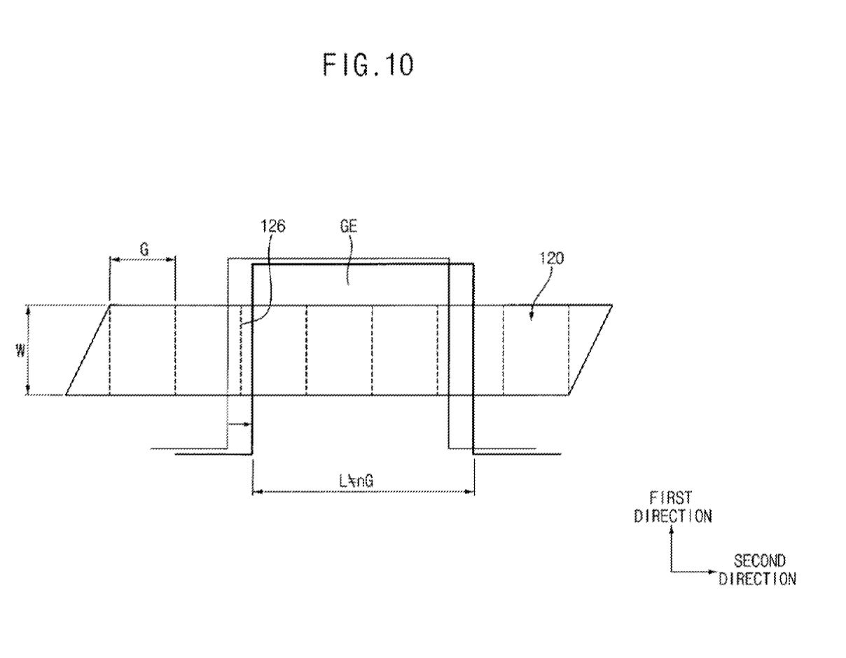

FIG. 9 is a plan view showing the relation between a gate electrode and grain boundaries, when width of the gate electrode is n-times of distance between the grain boundaries. FIG. 10 is a plan view showing the relation between a gate electrode and grain boundaries, when width of the gate electrode is not n-times of distance between the grain boundaries.

Referring to FIG. 9, a width L of a second direction of a gate electrode GE is natural number-times of a distance between grain boundaries 126. For example, the width L of the gate electrode GE toward the second direction may be represented by the following equation 3.

L=n×G (n is a natural number) [Equation 3]

A gate electrode GE in FIG. 9 may be shifted toward the second direction by the patterning error. When the width L of the gate electrode GE in the second direction is natural number-times of the distance between grain to boundaries 126, the number of grain boundaries in a region corresponding to the gate electrode GE, or the channel part 122, is constant. For example, in FIG. 9, the number of the grain boundaries may be three before and after shift of the gate electrode GE.

On the other hand, referring to FIG. 10, the width L of a gate electrode GE in the second direction is not natural number-times of distance between grain boundaries 126. A width L of the gate electrode GE toward the second direction may be represented by the following equation 4.

L≠n×G (n is a natural number) [Equation 4]

When the width L of the gate electrode GE in the second direction is not natural number-times of the distance between the grain boundaries 126, the number of the grain boundaries in the channel part 122 may be changed by the patterning error according to the shift of the gate electrode GE. For example, in FIG. 10, the number of the grain boundaries may be four before the shift, and the number of the grain boundaries may be three after the shift.

When the width L of the gate electrode GE in the second direction is natural number-times of the distance between the grain boundaries 126, the number of the grain boundaries in the channel part 122, are constant in spite of the patterning error. Thus, electrical mobility in the channel part 122 is not affected by the patterning error.

When the side of the gate electrode GE is inclined with respect to the longitudinal direction of the grain boundaries 126 of the semiconductor layer 120 and the width L of the gate electrode GE in the second direction is natural number-times of the distance between the grain boundaries 126, electrical characteristics of the semiconductor layer 120 is enhanced.

FIG. 11 to FIG. 14 are plan views showing a method of manufacturing an array substrate in accordance with an embodiment of the present invention.

FIG. 11 is a drawing showing steps for forming silicon layers having grain boundaries disposed on a transparent substrate along a first direction.

Referring to FIG. 11, a first silicon layer (not shown) is disposed on the transparent substrate. The first silicon layer includes amorphous silicon. For example, the first silicon layer may be deposited by chemical vapor deposition (CVD).

The whole region of the first silicon layer is crystallized by scanning laser beam irradiated onto the first silicon layer with shifting a mask (not shown) having a plurality of slits toward a first direction. This crystallization method is referred to as sequential lateral solidification (SLS).

By scanning the laser beam onto the first silicon layer with shifting the laser beam, the first silicon layer is changed into a second silicon layer including poly-silicon. Grain boundaries 126 are disposed along the first direction on the second silicon layer.

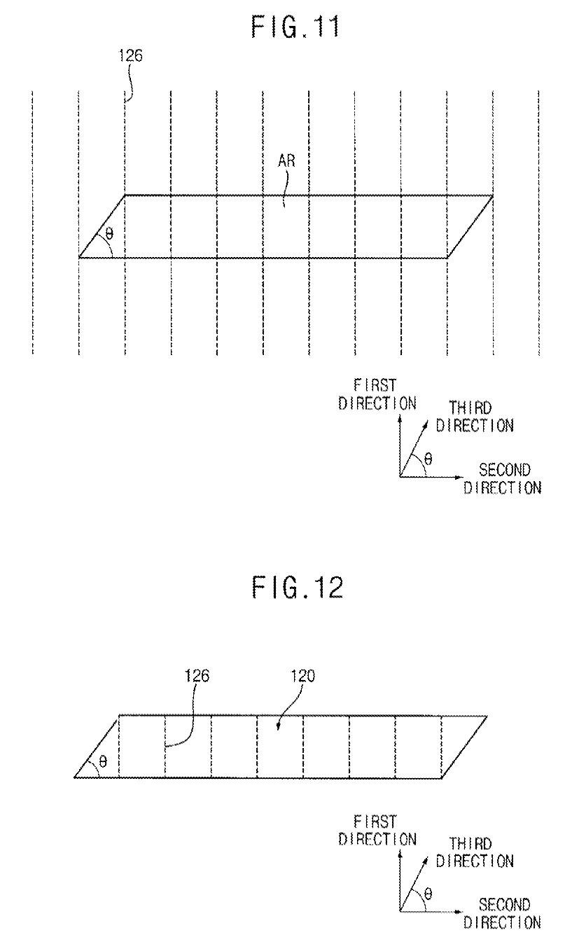

FIG. 12 is a view forming a semiconductor layer by etching a portion of a silicon layer having grain boundaries.

Referring to FIG. 11 and FIG, 12, for example, by etching the second to silicon layer except a portion AR, a semiconductor layer 120 is formed. Alternatively, the semiconductor layer 120 may be formed by oxidizing the second layer except for the portion AR. For example, the semiconductor layer 120 may be an un-oxidized portion of the second silicon layer.

The semiconductor layer 120 is disposed along the second direction substantially perpendicular to the first direction. For example, the semiconductor layer 120 may have a shape of a parallelogram or a rectangular form when viewed on a plane.

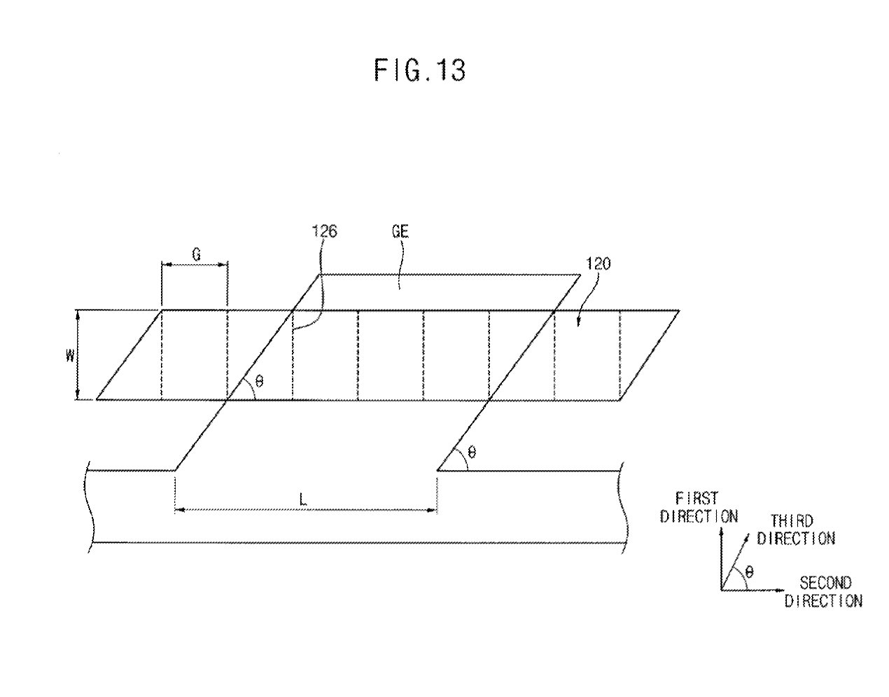

FIG. 13 is a view forming a first insulating layer, gate lines and gate electrodes.

Referring to FIG. 13, a first insulating layer (not shown) covers a semiconductor layer 120, and is disposed on the transparent substrate. The first insulating layer may be formed by depositing silicon oxide (SiOx) and/or silicon nitride (SiNx).

Gate lines GL and gate electrodes GE are formed on the first insulating layer. For example, the gate lines GL may be formed along the second direction on the first insulating layer. The gate electrodes GE are branched from the gate lines GL, and a side of each of the gate electrodes GE crosses a side of the semiconductor layer 120. The gate electrodes GE are formed along a third direction. The third direction and a second direction make an acute angle θ. For examples the gate electrodes GE may have a shape of a parallelogram when viewed on a plane.

After forming the gate electrodes GE and the gate lines GL, an ion doped part (not shown) is formed by doping ions into the semiconductor layer 120. For example, each of the gate electrodes GE may have a function as a mask. In addition, each of the gate electrodes GE may prevent movement of the ions. Thus, a channel part without the ions and the ion doped part doped with the ions are formed.

For example, the ions may be doped at a low density into a domain of the semiconductor layer 120 except for the channel pad. The ions are doped at a high density into a portion of the domain doped with low density. Thus, the ion doped part is separated as a low density doped part and a high density doped part.

The low density doped part is disposed at both sides of the channel part. The high density doped part is disposed at both edges of the low density doped part.

In an embodiment, relation of an angle θ between the gate electrode and a second direction, distance G between grain boundaries 126, width W toward a first direction of the semiconductor layer 120 and width L toward a second direction of gate electrode is represented by the equations 1 and 3.

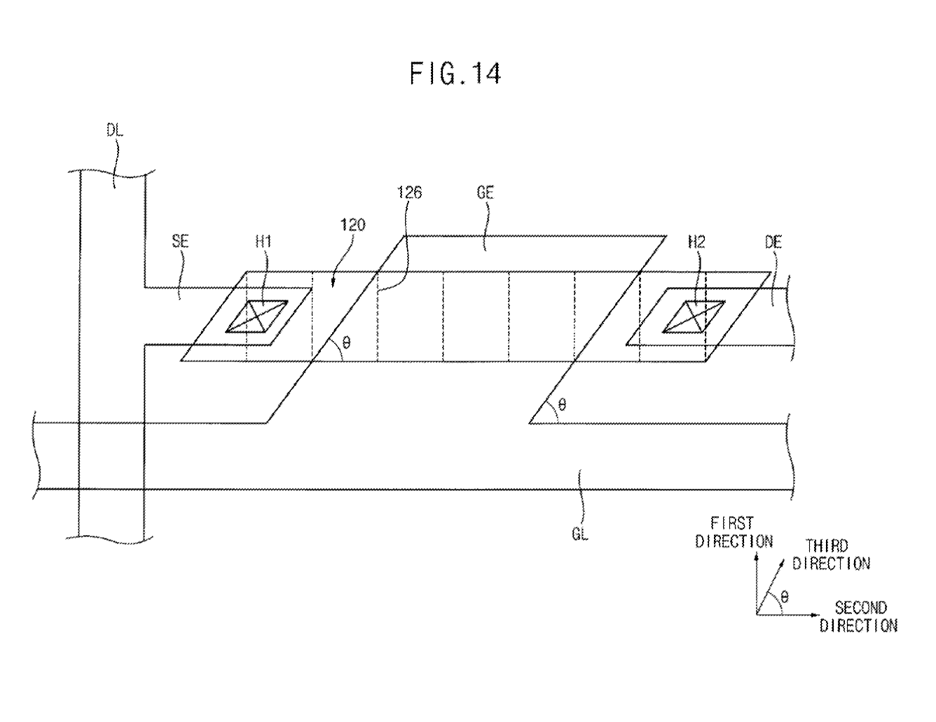

FIG. 14 is a plan view forming a second insulating layer, data lines, source electrodes, drain electrodes, a protecting layer and pixel electrodes.

Referring to FIG. 14, a second insulating layer (not shown) covers the gate line GL and the gate electrode GE, and is disposed on the first insulating layer.

A portion of the first and second insulating layer is etched so that the first and second contact holes H1 and H2 are formed on the semiconductor layer 120. The gate electrode GE is in the middle of the first and second contact holes H1 and H2. For example, the first and second contact holes H1 and H2 may be disposed on the high density ion doped part of the ion doped part.

A data line DL, a source electrode SE and a drain electrode DE are formed on the second insulating layer. The date line DL crosses the gate line GL. The data line DL is disposed along a first direction. The source electrode SE is branched from the data line DL toward a second direction. The source electrode SE overlaps a portion of the semiconductor layer 120. The source electrode SE is electrically connected to the semiconductor layer 120.

A protecting layer (not shown) is formed on the second insulating layer. In addition, the protecting layer covers the data line DL, the source electrode SE and the drain electrode DE. A portion of the protecting layer is etched so that a third contact hole is formed on the drain electrodes DE.

A pixel electrode including transparent conductive material is formed on the protecting layer. The pixel electrode is electrically connected to the drain electrode DE through the third contact hole.

Through the above steps, an array substrate of the exemplary embodiments can be manufactured. When a side of the gate electrode GE is inclined with respect to a direction of the grain boundaries 126 of the semiconductor layer 120, and a width L of the gate electrode GE in the second direction is natural number-times of a distance between the grain boundaries 126, electrical characteristics of the semiconductor layer 120 is enhanced.

According to the exemplary embodiments, an acute angle between a gate electrode and a grain boundary prevents grain boundaries from being formed at a boundary between a channel part and an ion doped part. Thus, electrical mobility of a semiconductor layer is enhanced.

In addition, when a width of a gate electrode in a second direction is natural number-times of a distance between grain boundaries, the number of the grain boundaries in the channel part is constant in spite of patterning error. Thus, electrical mobility in the channel part 122 is not affected by the patterning error, and electrical characteristics of a thin film transistor may be improved.

Although exemplary embodiments of the present invention have been described herein with reference to the accompanying drawings, it is to be understood that the present invention should not be limited to those precise embodiments and that various other changes and modifications may be made by one of ordinary skill in the related art without departing from the scope or spirit of the invention. All such changes and modifications are intended to be included within the scope of the invention as defined by the appended claims.

What is claimed is:

1. A thin film transistor comprising:
a semiconductor layer including a plurality of grain boundaries disposed along a first direction,
a source electrode;
a drain electrode adjacent to the source electrodes and
a gate electrode facing the source and drain electrodes with the semiconductor layer interposed between the gate electrode and the drain and source electrodes, the gate electrode including a side surface forming an acute angle θ with respect to a second direction substantially perpendicular to the first direction, and the acute angle θ being represented by the following equation:
tan(θ)=W/G
wherein G is a distance between the grain boundaries, and W is a width of the semiconductor layer toward the first direction.

2. The thin firm transistor of claim 1, wherein a width L of the gate electrode in the second direction satisfies the following equation:
L=n×G
wherein n is a natural number.

3. The thin film transistor of claim 1, wherein the semiconductor layer has a parallelogram shape, and the acute angle is substantially the same as an angle of the parallelogram.

4. The thin film transistor of claim 1, wherein the width of the semiconductor layer in the first direction has a range from about 1.5 μm to about 100 μm.

5. The thin film transistor of claim 1, wherein the distance between the grain boundaries has a range from about 1.5 μm to about 10 μm.

6. The thin film transistor of claim 1, wherein a width of the gate electrode in the second direction has a range from about 1.5 μm to about 100 μm.

7. An array substrate including pixel electrodes disposed in a matrix and a plurality of thin film transistors driving the pixel electrodes, each of the thin film transistors comprising:
a semiconductor layer having a plurality of grain boundaries disposed along a first direction;
a source electrode;
a drain electrode adjacent to the source electrode; and
a gate electrode facing the source and drain electrodes with the semiconductor layer interposed between the gate electrode and the drain and source electrodes, the gate electrode including a side surface forming an acute angle θ with respect to a second direction substantially perpendicular to the first direction, and the acute angle θ being represented by the following equation:
tan(θ)=W/G
wherein G is a distance between the grain boundaries, and W is a width of the semiconductor layer toward the first direction.

8. The array substrate of claim 1, wherein a width L of the gate electrode in the second direction satisfies the following equation:
L=n×G
wherein n is a natural number.

9. A method of manufacturing an array substrate, comprising:
forming a semiconductor layer having a plurality of grain boundaries along a first direction on a substrate;
forming a gate electrode along a third direction making an acute angle with a second direction substantially perpendicular to the first direction, the gate electrode partially overlapping the semiconductor layer; and
forming a source electrode electrically connected to a first portion of the semiconductor layer and a drain electrode electrically connected to a second portion of the semiconductor layer.

10. The method of claim 9 wherein forming the semiconductor layer comprises:
forming a first silicon layer including amorphous silicon (a-Si) on the substrate;
scanning a laser beam onto the first silicon layer to form a second silicon layer including poly-silicon having the grain boundaries; and
partially etching the second semiconductor layer to form the semiconductor layer.

11. The method of claim 9, wherein forming the semiconductor layer comprises:
forming a first silicon layer including amorphous silicon (a-Si) on the substrate;
scanning a laser beam onto the first silicon layer to form a second silicon layer including poly-silicon having the grain boundaries; and
partially oxidizing the second silicon layer to form the semiconductor layer.
